(19) United States
(12) Patent Application Publication
(10) Pub. No.: US 2016/0141390 A1
(43) Pub. Date: May 19, 2016

(54) METHOD FOR MANUFACTURING DISPLAY PANEL

(71) Applicant: InnoLux Corporation, Miao-Li County (TW)

(72) Inventors: Ker-Yih KAO, Miao-Li County (TW); Chin-Lung TING, Miao-Li County (TW); Jung-Fang CHANG, Miao-Li County (TW); Chien-Chung WANG, Miao-Li County (TW)

(21) Appl. No.: 14/923,473

(22) Filed: Oct. 27, 2015

(30) Foreign Application Priority Data
Nov. 14, 2014 (TW) 103139522

(51) Int. Cl. H01L 29/66; H01L 27/12; H01L 29/417; H01L 29/49

(52) U.S. Cl. CPC H01L 29/66742; H01L 29/4908; H01L 27/1225; H01L 29/41733

(57) ABSTRACT

A method for manufacturing display panel is disclosed, which comprises: (A) providing a substrate, an oxide semiconductor layer disposed on the substrate, and a gate electrode disposed on the substrate and corresponding to the oxide semiconductor layer; (B) forming a metal layer on the oxide semiconductor layer; (C) forming a photoresist on the metal layer, and etching the metal layer to form a source electrode and a drain electrode; (D) heating the photoresist and the photoresist covers at least partial of side walls of the source electrode and the drain electrode; (E) applying an alkaline solution on the substrate; and (F) removing the photoresist to expose the source electrode and the drain electrode.

### CROSS REFERENCE TO RELATED APPLICATION

This application claims the benefits of the Taiwan Patent Application Serial Number 103139522, filed on Nov. 14, 2014, the subject matter of which is incorporated herein by reference.

### BACKGROUND OF THE INVENTION

1. Field of the Invention

The present disclosure relates to a method for manufacturing display panel, more particular, to a method for manufacturing display panel having better reliability.

2. Description of Related Art

As the display technology continues to progress, the demand of users is now toward smaller, thinner, and lighter electronic devices. Therefore, the display devices available in the current market have changed from the previous cathode ray tube display devices to liquid crystal display devices (LCD) or organic light emitting display devices (OLED).

Thin film transistor is now widely applied in many advanced display devices. Due to the large competition in the market, the need for better size and display quality (such as the display color saturation) for display devices increases. At the same time, the thin film transistor is also required to have better electrical performance and stability. During the manufacturing process of the thin film transistor, the preparation of the metal electrode usually comprises the steps of depositing a metal layer on a substrate, forming a photoresist pattern by photolithography, and then etching the metal layer below the photoresist to obtain a metal layer with desired patterns. However, during the etching process, the semiconductor layer may be damaged by the product (and the remaining etchant) of the etching reaction or the product of the etching reaction may accumulate on the semiconductor layer; thus, causing the threshold voltage of the thin film transistor to shift negatively or affecting the reliability of the device operation.

Accordingly, there is a need to provide a manufacturing method of display panel where the problems mentioned above could be improved. Consequently, the properties of the thin film transistor can also be improved and the display quality of the display devices may be increased as well.

### SUMMARY OF THE INVENTION

The object of the present invention is to provide a method for manufacturing a display panel, so that a display panel with improved reliability may be prepared.

To achieve the above object, the method for manufacturing a display panel comprises the following steps of: (A) providing a substrate; an oxide semiconductor layer disposed on the substrate; and a gate electrode disposed on the substrate and corresponding to the oxide semiconductor layer; (B) forming a metal layer on the oxide semiconductor layer; (C) forming a photoresist on the metal layer, and etching at least partial of the metal layer to form a source electrode and a drain electrode, wherein, the source electrode is separated from the drain electrode; (D) heating the photoresist and the photoresist covers at least partial of side walls of the source electrode and the drain electrode; (E) applying an alkaline solution on the substrate; and (F) removing the photoresist to expose the source electrode and the drain electrode.

In step (A), the gate electrode may be disposed on the oxide semiconductor layer; or the gate electrode is disposed between the substrate and the oxide semiconductor layer.

In step (B), the metal layer may have a single-layered structure or a multi-layered structure comprising Al, wherein the multi-layered structure may comprise at least two metals selected from the group consisting of Mo, Al, and Ti or combinations thereof.

In step (C), the metal layer is etched by an etchant; the etchant may be one or more selected from the group consisting of nitric acid, phosphoric acid, and acetic acid.

In step (D), with respect to 100% of a total area of the side walls, the area of the side walls covered with the photoresist is greater than 50%. It is preferable that the photoresist completely covers the side walls of the source electrode and the drain electrode. In addition, the photoresist may be heated in a range from 100° C. to 150° C. for 2 to 60 minutes, wherein 110° C. to 140° C. for 3 to 30 minutes is preferable.

In step (E), the alkaline solution may be a developing solution comprising hydroxide ions (OH), and a pH value of the alkaline solution may be greater than pH 7 and less than or equal to pH 14. Preferably, the pH value of the alkaline solution ranges from pH 12 to pH 14.

According to the method for manufacturing the display panel of one of the embodiment of the present invention, after the metal layer is etched in step (C), the photoresist is heated in step (D) and the photoresist may cover at least partial of the side walls of the source electrode and the drain electrode. Therefore, when the alkaline solution is applied in step (E), the photoresist may protect the source electrode and the drain electrode from eroded by the alkaline solution. Therefore, when the subsequent layers are stacked on the source electrode and the drain electrode, pores with larger size caused by the erosion may not be generated in the thin film transistor substrate. Therefore, the display panel prepared by the method of one of the embodiment of the present invention has high reliability. Moreover, the alkaline solution applied in step (E) may neutralize the product generated by the etching reaction to prevent damaging the oxide semiconductor layer, thus, the negative shift of the threshold voltage may be prevented, and the phenomena of Mura may be reduced. Therefore, the percentage of defect on the product may be reduced.

Further, one of the embodiment of the present invention also provides a display panel, which is manufactured by the above mentioned method. The display panel comprises: a first substrate; an oxide semiconductor layer disposed on the first substrate; a gate electrode disposed on the first substrate and corresponding to the oxide semiconductor layer; a source electrode and a drain electrode disposed on the oxide semiconductor layer, wherein the source electrode and the drain electrode include at least a side wall having at least a recessed portion, wherein the ratio of the area of the recessed portion to the total area of the side walls is greater than 0% and less than or equal to 50%; a second substrate disposed on an opposite side of the first substrate; and a plurality of liquid crystal units disposed between the first substrate and the second substrate.

### BRIEF DESCRIPTION OF THE DRAWINGS

FIG. 1A to FIG. 1G shows a schematic diagram of the method for manufacturing of a preferred embodiment of the present invention;

FIG. 1E′ is a schematic diagram showing another embodiment of FIG. 1E;

FIG. 2 shows a schematic diagram of a thin film transistor of another preferred embodiment of the present invention;

FIG. 3 shows a schematic diagram of a thin film transistor of yet another preferred embodiment of the present invention;

FIG. 4 shows a schematic diagram of a thin film transistor of yet another preferred embodiment of the present invention;

FIG. 5 shows a schematic diagram of a display panel of an embodiment of the present invention;

FIG. 6 shows a schematic diagram of a thin film transistor prepared by the comparative example of the present invention.

### DETAILED DESCRIPTION OF THE EMBODIMENT

Hereafter, examples will be provided to illustrate the embodiments of the present invention. Other advantages and effects of the invention will become more apparent from the disclosure of the present invention. Other various aspects also may be practiced or applied in the invention, and various modifications and variations can be made without departing from the spirit of the invention based on various concepts and applications.

### Embodiment

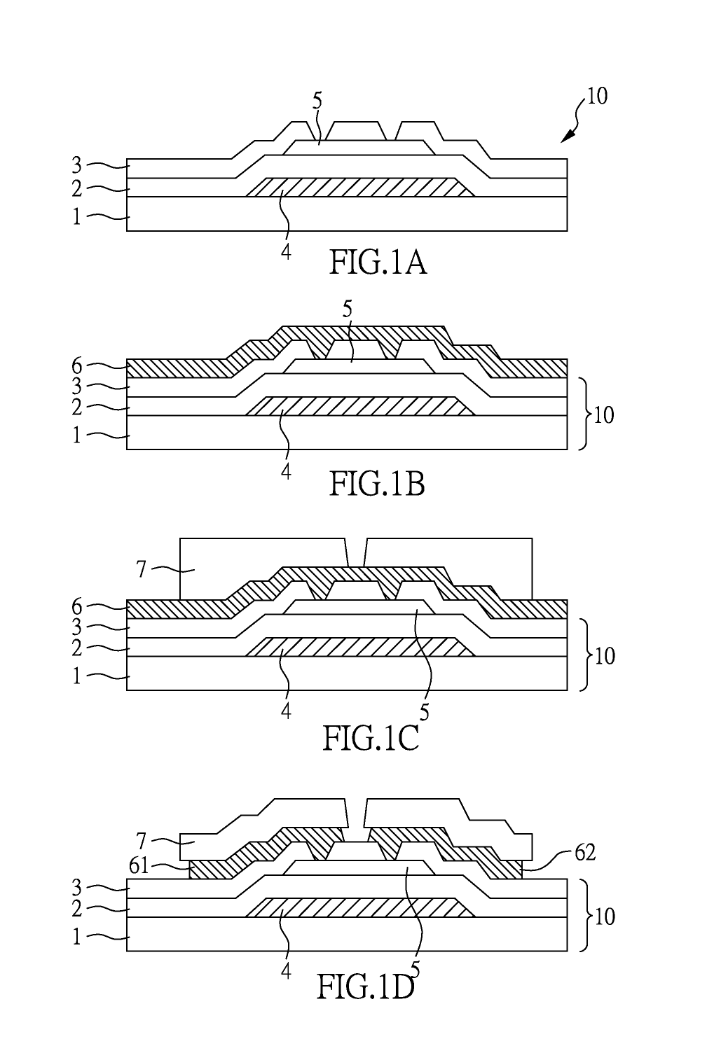

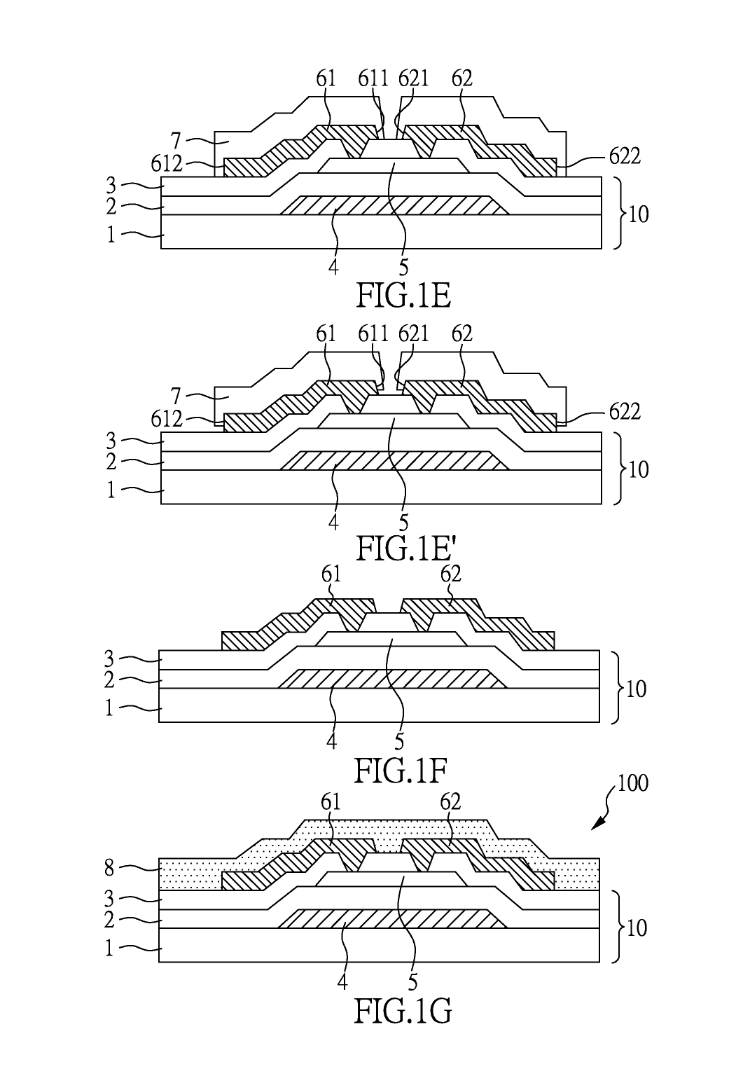

With reference to FIG. 1A to FIG. 1G, there is shown a schematic diagram of the method for manufacturing a display panel of the present disclosure.

First of all, as shown in FIG. 1A, there is provided a substrate 1, a first insulating layer 2 and a second insulating layer 3, which are sequentially disposed on the substrate 1; a gate electrode 4 disposed on the substrate 1 and locating between the first insulating layer 2 and the substrate 1; and an oxide semiconductor layer 5 disposed on the substrate 1 and locating between the first insulating layer 2 and the second insulating layer 3; wherein the gate electrode 4 corresponds to the oxide semiconductor layer 5.

Further, as shown in FIG. 1B, a metal layer 6 is formed on the oxide semiconductor layer 5. Herein, the metal layer 6 having a single-layer or a multi-layer structure may be formed by various deposition methods, such as electroplating, electroless plating, evaporation, sputtering, or combinations thereof. In the present invention, the metal layer may has a single-layered structure or a multi-layered structure comprising Al, wherein the multi-layered structure may comprise at least two metals selected from the group consisting of Mo, Al, and Ti or combinations thereof. For example, the metal layer may have a three-layered structure of Mo/Al/Mo, Ti/Al/Ti, or Ti/Al/Mo.

Please now refer to FIG. 1C, a photoresist 7 is formed on the metal layer 6 by photolithography, and the metal layer 6 is etched by an etchant for patterning. After the metal layer 6 is patterned as shown in FIG. 1D, a source electrode 61 and a drain electrode 62 are formed, and the source electrode 61 and the drain electrode 62 separate from each other. In addition, the etchant may comprise at least one selected from the group consisting of nitric acid, phosphoric acid, and acetic acid or combinations thereof. For example, an etchant comprises nitric acid, phosphoric acid, and acetic acid. Further, various method may be used in this step for patterning the metal layer. For example, wet etching, electrochemical etching, or a combination of thereof for defining the source electrode 61 and the drain electrode 62 can be used.

Next, refer to FIG. 1E, the photoresist 7 is heated and the photoresist 7 may cover at least partial of the side walls 611, 612 of the source electrode 61, and the side walls 621, 622 of the drain electrode 62. The photoresist 7 may be heated to 100° C. to 150° C. for 2 to 60 minutes, wherein 110° C. to 140° C. for 3 to 30 minutes is preferable. However, the heating condition may be adjusted by a person skilled in the art according to the species of the photoresist and the heating mode. In addition, with respect to 100% of the total area of any one of the side walls 611, 612, 621, or 622, the area of the side walls 611, 612, 621, or 622 covered with the photoresist 7 is greater than 50% after the photoresist 7 is heated. For example, with respect to 100% of the total area of the side wall 611, the area of the side wall 611 covered with the photoresist 7 is greater than 50% after the photoresist 7 is heated. But it is preferable that the photoresist 7 completely covers the side walls 611, 612, 621, and 622. FIG. 1E shows a schematic diagram that the photoresist 7 completely covers the side walls 611, 612, 621, or 622. Also, please refer to FIG. 1E′, which shows a schematic diagram that approximately 60% of the area of the side walls 611, 612, 621, and 622 is covered with the photoresist 7. In one of the embodiment of the present invention, “completely covers the side walls” refers to a case that the total area of the side walls 611, 612, 621, or 622 is covered with the photoresist 7, which means that the 100% of the area of the side walls 611, 612, 621, or 622 is covered with the photoresist 7.

As shown in FIG. 1F, an alkaline solution is applied to the substrate 1. More specifically, the alkaline solution is applied to the laminate structure of photoresist 7/source electrode 61 and drain electrode 62/second insulating layer 3. The photoresist 7 is removed by oxygen or acidic solution in order to expose the source electrode 61 and the drain electrode 62. Finally, a third insulating layer 8 may be disposed on the source electrode 61 and the drain electrode 62 to accomplish a thin film transistor 100 depending on the actual needs. The alkaline solution may be a developing solution comprising hydroxide (OH⁻) ions, and a pH value of the alkaline solution may be greater than pH 7 and less than or equal to pH14, wherein the pH value of the alkaline solution preferably ranges from pH 12 to pH 14. However, the pH value of the alkaline solution may be adjusted by a person skilled in the art based on the actual etching reaction. For example, when an etchant comprising nitric acid, phosphoric acid, and acetic acid is used for etching the three-layered metal layer Mo/Al/Mo, hydrogen ions (H⁺) may be included in the product generated by the etching reaction. Therefore, an alkaline solution is selected to neutralize the hydrogen ions for preventing the negative shift of the threshold voltage caused by the damages of the oxide semiconductor layer 5. Thus the phenomena of Mura may be reduced.

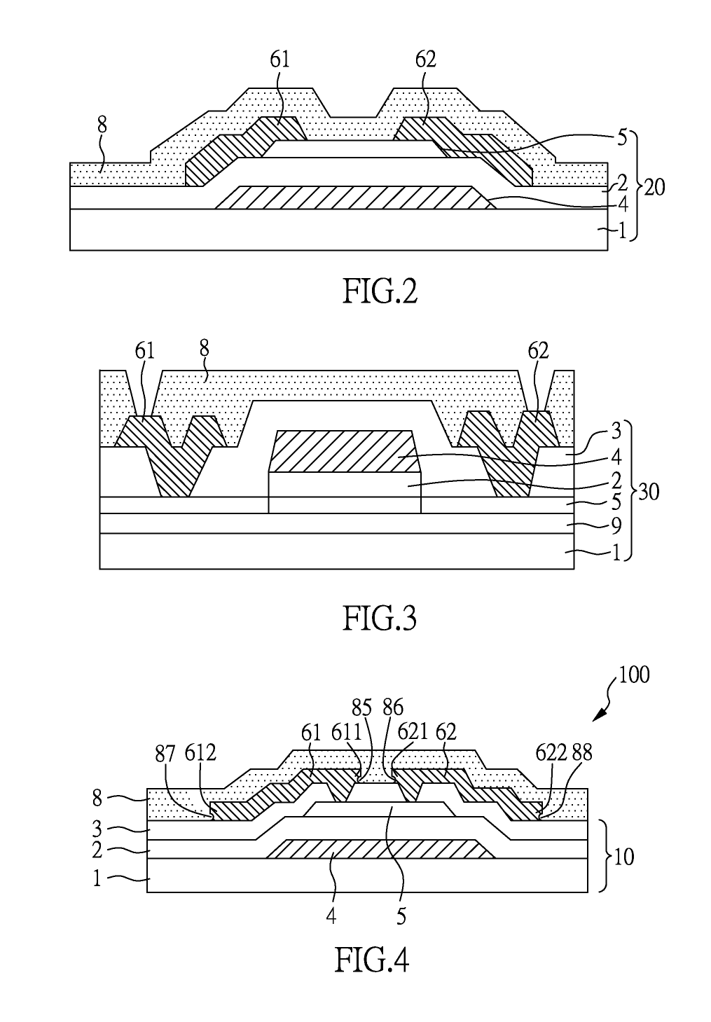

In the present embodiment, FIG. 1G shows a bottom gate type thin film transistor having an etching stop layer structure (ESL), wherein the source electrode 61 and the drain electrode 62 are disposed on the oxide semiconductor layer 5, and the gate electrode 4 is disposed between the substrate 1 and the oxide semiconductor layer 5. The thin film transistor may be prepared by a known method in the art, thus the description of the preparation method is omitted. The structure of the thin film transistor that the present manufacturing method can be applied may be easily adjusted by a person skilled in the art, and may be a back channel etching structure (BCE) shown in FIG. 2, or a top gate type thin film transistor shown in FIG. 3.

The manufacturing method of the thin film transistor with the back channel etching structure shown in FIG. 2 comprises: providing a substrate 1; a first insulating layer 2 disposed on the substrate 1; a gate electrode 4 disposed on the substrate 1 and located between the first insulating layer 2 and the substrate 1; and a oxide semiconductor layer 5 disposed on the first insulating layer 2; wherein the gate electrode 4 corresponds to the oxide semiconductor layer 5. It is noted that the manufacturing method of back channel etching structure shown in FIG. 2 is similar to that mentioned above, except that the second insulating layer 3 is not disposed herein. Therefore, the description of the manufacturing method need not be repeated.

The manufacturing method of the top gate type thin film transistor substrate shown in FIG. 3 comprises following steps: providing a substrate 1; a buffer layer 9 disposed on the substrate 1; an oxide semiconductor layer 5 disposed on the buffer layer 9; a first insulating layer 2 and a second insulating layer 3 sequentially disposed on the oxide semiconductor layer 5; and a gate electrode 4 disposed on the substrate 1 and between the first insulating layer 2 and the second insulating layer 3; wherein the gate electrode 4 corresponds to the oxide semiconductor layer 5. Besides, the other steps are similar to those mentioned above; therefore, the description of the manufacturing method need not be repeated.

In addition, the substrate 1 may be a general substrate used in the art, such as glass substrate, plastic substrate, silicon substrate, and ceramic substrate. Further, the material used for metal layer 6 and the gate electrode 4 may be a general conductive material used in the art, such as metal, alloy, metal oxide, or other electrode material used in the art; wherein metal is preferred but the present invention is not limited thereto. If required, a composite electrode of a transparent electrode and a semi-transparent electrode may be used, such as a composite electrode of a TCO electrode and a platinum thin film electrode. As for the oxide semiconductor layer 5, an oxide semiconductor material in the art may be used, such as indium gallium zinc oxide (IGZO), indium tin zinc oxide (ITZO), or other metal oxide semiconductors. In addition, the material of the first insulating layer 2 and the second insulating layer 3 may be a passivation material known in the art, such as silicon nitride (SiNx), silicon oxide (SiOx), or combination thereof. However, the present invention is not limited thereto.

Accordingly to the method for manufacturing the display panel of the present disclosure, the photoresist 7 is heated after the metal layer 6 is etched, and the photoresist 7 flows onto and covers at least partial of the side walls 611, 612, 621, 622 of the source electrode 61 and the drain electrode 62. Therefore, the side walls 611, 612, 621, and 622 may be protected, and the eroded area may be reduced when the alkaline solution is applied thereon. Thus, the defect of the thin film transistor 100 generated due to the erosion will be effectively reduced when the subsequent layers laminate onto the source electrode 61 and the drain electrode 62. Also, the negative shift of the threshold voltage may be prevented, and the phenomena of Mura may be effectively reduced. Accordingly, the thin film transistor 100 manufactured by the method of the present disclosure is highly reliable. It should be noted that, when the area of the side walls 611, 612, 621, 622 covered by the photoresist 7 is ranging from 50%˜100%, a recessed portion may still be formed on the side walls 611, 612, 621, 622. However, the area of the recessed portion is only 0.1% to 50% with respect to the total area of the side walls 611, 612, 621, 622, thus the high reliability of the display panel may be confirmed. When the area of the recessed portion is 0.1% to 30% with respect to the total area of the side walls 611, 612, 621, 622, the display panel may have higher reliability. FIG. 4 shows schematic diagram of the thin film transistor substrate 100 which the area of the recessed portion 85, 86, 87, 88 is approximately 30% with respect to the total area of the side walls 611, 612, 621, 622.

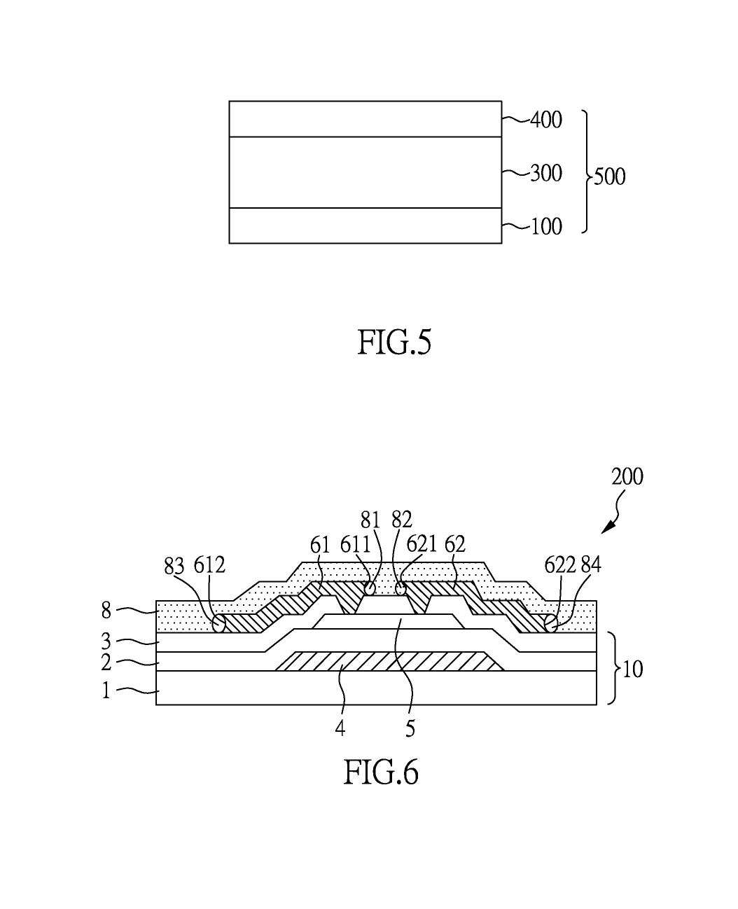

The thin film transistor substrate manufactured by the method of the present disclosure may be applied to a display panel. For example, display units may be disposed on the thin film transistor substrate, and an opposite substrate may be disposed on the display unit. More specifically, as shown in FIG. 5, when the thin film transistor substrate 100 is applied to a liquid crystal display device, the accomplished display device 500 may further comprises a liquid crystal units 300 that disposed on the thin film transistor substrate 100, a color filter and a black matrix layer (not shown) that disposed on the opposite substrate 400, and a back light module (not shown) disposed under the thin film transistor substrate 100. Alternatively, when the thin film transistor substrate 100 is applied to an organic light emitting display device, the display device further comprises an organic light emitting diode and a package substrate that disposed on the thin film transistor substrate. In addition, the display device may be applied to any one of the electronic devices in the art, such as display devices, mobile phones, laptops, cameras, video recorders, audio players, navigation devices, or televisions.

Therefore, according to the method for manufacturing the display panel, a display panel may be manufactured, wherein the display panel comprises: a first substrate; an oxide semiconductor layer disposed on the first substrate; a gate electrode disposed on the substrate and corresponding to the oxide semiconductor layer; a source electrode and a drain electrode disposed on the oxide semiconductor layer, wherein the source electrode and the drain electrode include at least a side wall having at least a recessed portion, wherein an area of the recessed portion with respect to a total area of the side wall is greater than 0% and less than or equal to 50%; a second substrate disposed on an opposite side of the first substrate; and a plurality of liquid crystal units disposed between the first substrate and the second substrate.

### Comparative Embodiment

Please refer to FIG. 6, which shows the thin film transistor substrate 200 prepared by the present comparative embodiment. In the comparative embodiment, the manufacturing process is substantially the same as the above embodiment except that the photoresist 7 is not heated after the metal layer 6 is etched. Briefly, a thin film transistor substrate 200 is accomplished by the following steps comprising: providing a substrate 1, sequentially disposing a first insulating layer 2 and a second insulating layer 3 on the substrate 1, disposing a gate electrode 4 on the substrate 1 and between the first insulating layer 2 and the substrate 1, disposing a oxide semiconductor layer 5 on the substrate 1 and between the first insulating layer 2 and the second insulating layer 3, forming a metal layer 6 on the structure obtained from the above steps, forming a photoresist 7 on the metal layer 6 by photolithography and etching the metal layer 6 using an etchant, after applying an alkaline solution on the substrate 1, removing the photoresist 7 to expose the source electrode 61 and the drain electrode 62, and disposing a third insulating layer 8 on the source electrode 61 and the drain electrode 62.

With reference to the thin film transistor substrate 200 shown in FIG. 6, a large area of the side walls 611, 612, 621, or 622 of the source electrode 61 and the drain electrode 62 is eroded by the alkaline solution, and the third insulating layer 8 subsequently disposed on the source electrode 61 and the drain electrode 62 is unable to completely filled the eroded portions, thus forming pores 81, 82, 83, and 84 in the accomplished thin film transistor substrate 200. Therefore, the reliability of the thin film transistor 200 is poor.

It should be understood that these examples are merely illustrative of the present invention and the scope of the invention should not be construed to be defined thereby, and the scope of the present invention will be limited only by the appended claims.

What is claimed is:

1. A method for manufacturing a display panel, comprising:
(A) providing a substrate; an oxide semiconductor layer disposed on the substrate; and a gate electrode disposed on the substrate and corresponding to the oxide semiconductor layer;
(B) forming a metal layer on the oxide semiconductor layer;
(C) forming a photoresist on the metal layer, and etching at least partial of the metal layer to form a source electrode and a drain electrode;
(D) heating the photoresist and the photoresist covers at least partial of side walls of the source electrode and the drain electrode;
(E) applying an alkaline solution on the substrate; and
(F) removing the photoresist to expose the source electrode and the drain electrode.

2. The method of claim 1, wherein in step (A), the gate electrode is disposed on the oxide semiconductor layer.

3. The method of claim 1, wherein in step (A), the gate electrode is disposed between the substrate and the oxide semiconductor layer.

4. The method of claim 1, wherein in step (B), the metal layer comprises Al.

5. The method of claim 1, wherein the metal layer has a multi-layered structure, and the multi-layered structure comprises at least two metals selected from the group consisting of Mo, Al, and Ti or combinations thereof.

6. The method of claim 1, wherein in step (D), the photoresist completely covers the side walls of the source electrode and the drain electrode.

7. The method of claim 1, wherein in step (D), the photoresist is heated in a range from 100° C. to 150° C. for 2 to 60 minutes.

8. The method of claim 1, wherein in step (E), the alkaline solution comprises hydroxyl ions.

9. The method of claim 1, wherein in step (E), the pH value of the alkaline solution is ranging from pH12 to pH14.

10. A display panel, comprising
a first substrate;
an oxide semiconductor layer disposed on the first substrate;
a gate electrode disposed on the first substrate and corresponding to the oxide semiconductor layer;
a source electrode and a drain electrode disposed on the oxide semiconductor layer, wherein the source electrode and the drain electrode include at least a side wall having at least a recessed portion, wherein the ratio of the area of the recessed portion to the total area of the side wall is greater than 0% and less than or equal to 50%;
a second substrate disposed on an opposite side of the first substrate; and
a plurality of liquid crystal units disposed between the first substrate and the second substrate.
